(19) United States
(12) Patent Application Publication
(10) Pub. No.: US 2015/0000596 A1
(43) Pub. Date: Jan. 1, 2015

(54) MOCVD GAS DIFFUSION SYSTEM WITH GAS INLET BAFFLES

(71) Applicant: NATIONAL CENTRAL UNIVERSITY, Jhongli City (TW)

(72) Inventors: Shu-San HSIAU, Jhongli City (TW); Chun-Chung Liao, Jhongli City (TW); Tzu-Ching Chuang, Jhongli City (TW); Jyh-Chen Chen, Jhongli City (TW)

(73) Assignee: NATIONAL CENTRAL UNIVERSITY, Jhongli City (TW)

(21) Appl. No.: 13/963,579

(22) Filed: Aug. 9, 2013

(30) Foreign Application Priority Data
Jun. 26, 2013 (TW) 102122802

(51) Int. Cl. C23C 16/18; C23C 16/455

(52) U.S. Cl. CPC C23C 16/18; C23C 16/45502
USPC 118/722

(57) ABSTRACT

The present invention discloses a MOCVD gas diffusion system with gas inlet baffles. With the adoption of multiple detachable air inlet baffles under the MO gas (Metal Organic gas) inlet and the hydride gas inlet, the gas diffusion system can easily and effectively reduce the pre-reaction of the MO gas and the hydride gas near the gas inlets, prevent metal diffusions around the inlets and make the metal layer generated on the wafers on the wafer carrier be very even, the MO gas used is also massively reduced to save great cost. The MOCVD process with the diffusion system of the present invention thus has a great potential in application to productions of high-performance LED epitaxy.

### BACKGROUND OF THE INVENTION

1. Technical Field

The present invention relates to a metal organic chemical vapor deposition (MOCVD) gas diffusion system, and more particularly, to an MOCVD gas diffusion system with gas inlet baffles.

2. Description of Related Art

The metal organic chemical vapor deposition (MOCVD) is known as a critical step in the manufacturing process of light emitting diode (LED) epitaxial wafers. In the MOCVD process, generally a group III gas material such as (CH₃)₃Ga (trimethyl gallium; TMGa) or (CH₃)₃In (trimethyl indium; TMIn) and a group V gas material such as AsH₃ (arsine), PH₃ (phosphine) or NH₃ are used as inlet gases. The inlet gases are carried by special carrier gases through gas inlets into a reaction chamber where epitaxial wafers such as GaAs wafers or sapphire wafers at a high temperature of about 400˜1200° C. are placed. There, the gas materials react with each other to form a reaction product which is then deposited on the epitaxial wafers to form a semiconductor crystalline film. Then, the epitaxial wafers having a semiconductor crystalline film thus formed thereon can be used as substrates for producing semiconductor light emitting devices such as light emitting diodes (LEDs).

The two inlet gas materials for the MOCVD process react with each other according to the following basic formulas:

TMGa(g)+AsH3(g)→* GaAs(s)+CH4(g); or

TMGa(g)+NH3(g)→GaN(s)+CH4(g)+N2(g)+H2(g).

The conventional MOCVD apparatus and system primarily comprise an electrically controlling (E-Control) unit, a reaction chamber, a gas mixing system and a back-end pipeline exhaust system. Because no gas inlet baffle is used in the conventional MOCVD gas transport system (or gas inlet system), it is often the case that the group III MO gas and the group V special gas pre-react with each other and the reaction product deposits near the gas inlets. This not only leads to waste of the gases, but also seriously affects the diffusion thickness uniformity, the run-to-run stability (i.e., reproducibility) and the through-put (the frequent maintenance will necessarily degrade the overall through-put) which are factors on which stringent requirements have been imposed in the MOCVD process.

The MOCVD epitaxial machine can deposit semiconductor crystalline films formed of different kinds of compounds by changing the precursors (i.e., the inlet gases), so they have found wide application. Currently, the mainstream conventional gas inlet diffusion systems of MOCVD epitaxial machines are classified as follows: 1. VEECO, in which a vertical gas inlet mode that uses a unique flow flange is adopted in conjunction with high-speed rotation of the stage (but without autorotation of wafers) to achieve a uniform flow field and to effectively increase the through-put and reduce the time duration and frequency of cleaning and maintenance; but it requires use of a large furnace body, and waste of gas materials is significant. 2. AIXTRON, in which a central nozzle arrangement is adopted to provide reaction gases and the wafer stage rotates at a high speed with autorotation of wafers to achieve a stable flow field; this makes the reaction furnace small and saves use of reaction gases, but the through-put often fails to fulfill the requirement. 3. THOMAS SWAN, in which a showerhead gas inlet mode is adopted in combination with medium- or low-speed rotation of the wafer stage to achieve uniform intake of gases; but in this air inlet mode, the distance between the gas inlets and the stage is very small (20 mm), so clogging of the showerhead holes may take place easily and this requires frequent cleaning.

As can be known from the above analysis, the mainstream conventional gas diffusion systems have respective advantages and disadvantages, and improve uniformity of the flow field within the reaction chamber mainly by modifying the gas inlet mode and designing the geometry and arraying of the gas inlet holes. However, none of the systems can surely improve the problem that the reaction gases entering the reaction chamber pre-react with each other around the gas inlet holes to produce reaction products that cause clogging of the gas inlets.

Performances of the MOCVD process is closely related to the quality, yield rate and through-put of the epitaxial wafers, so it is desirable for numerous LED manufacturers and the whole LED industry to provide an MOCVD gas diffusion system that has a short tact time, is simple, and is cheap in cost; that allows the semiconductor crystalline film to be deposited on a wafer surface uniformly; that effectively reduces pre-reaction of the MO gas and the hydride gas; and that reduces the usage of the MO gas.

### SUMMARY OF THE INVENTION

The present invention provides an MOCVD gas diffusion system with gas inlet baffles that effectively reduces pre-reaction of the MO gas and the hydride gas in a simple and rapid way during the MOCVD process to avoid deposition near the gas inlets; that allows the semiconductor crystalline film to be deposited on surfaces of a plurality of wafers on the wafer stage uniformly; and that reduces the usage of the MO gas. The MOCVD gas diffusion system of the present invention has a great potential of being applied to production of high-performance LED epitaxy.

The present invention provides a metal organic chemical vapor deposition (MOCVD) gas diffusion system with gas inlet baffles, comprising: a reaction chamber in the form of a hollow enclosure; a wafer stage, being fixedly disposed in the reaction chamber and having a central axis, the wafer stage being adapted to support a plurality of wafers and rotate about the central axis; at least, one first gas inlet, being formed at an upper portion of the reaction chamber and adapted to input a metal organic (MO) gas; at least one second gas inlet, being formed at the upper portion of the reaction chamber and separate from the first gas inlet, the second gas inlet being adapted to input a hydride gas; a plurality of gas inlet baffles, being obliquely movably disposed under the first gas inlet and the second gas inlet, wherein an upper layer opening and a lower layer opening exist between every two adjacent ones of the gas inlet baffles to allow the MO gas or the hydride gas to pass therethrough, and the gas inlet baffles are made of a material that does not react with the MO gas and the hydride gas; and a gas outlet, being formed at a lower portion of the reaction chamber and adapted to discharge the MO gas or the hydride gas or a mixture of the MO gas and the hydride gas.

Through implementation of the present invention, at least the following inventive effects can be achieved:

1. Pre-reaction of the MO gas and the hydride gas around the gas inlets can be effectively reduced in a rapid, simple and low-cost way to avoid deposition around the gas inlets during the MOCVD process;

2. the gas inlet baffles can be designed in a variety of ways to control uniformity of the semiconductor crystalline film in multiple sections;

3. by designing the gas inlet baffles to be detachable, the gas diffusion system can be cleaned and maintained rapidly and easily to improve the utilization factor of the machine and lower the production cost;

4. usage of the MO gas can be reduced to lower the cost of the MOCVD process; and

5. the tilt angle of the gas inlet baffles can be controlled to improve uniformity of the reaction gas field in the reaction chamber.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The structure as well as a preferred mode of use, further objects, and advantages of the present invention will be best understood by referring to the following detailed description of some illustrative embodiments in conjunction with the accompanying drawings, in which:

FIG. 1 is a cross-sectional view of an MO gas diffusion system with gas inlet baffles according to an embodiment of the present invention;

FIG. 2 is a perspective view of a gas inlet baffle according to an embodiment of the present invention;

FIG. 3 is a top view of another gas inlet baffle according to an embodiment of the present invention;

FIG. 4A is a longitudinal cross-sectional view of a gas inlet baffle according to an embodiment of the present invention;

FIG. 4B is a longitudinal cross-sectional view another gas inlet baffle according to an embodiment of the present invention;

FIG. 5A is a graph illustrating the MO gas concentration versus the distance in a region 5 mm below the gas inlet baffles when different width ratios of the upper surface to the lower surface of a gas inlet baffle are used according to an embodiment of the present invention;

FIG. 5B is a graph illustrating the MO gas concentration versus the distance in a region 0.1 mm above the wafer stage when different width ratios of the upper surface to the lower surface of a gas inlet baffle are used according to an embodiment of the present invention;

FIG. 6A is a graph illustrating the MO gas concentration versus the distance in a region 0.1 mm above the wafer stage when gas inlet baffles having different included angles are used according to an embodiment of the present invention;

FIG. 6B is a graph illustrating the utilization factor of the MO gas in a region 0.1 mm above the wafer stage when a first side surface of a gas inlet baffle is inclined at different angles according to an embodiment of the present invention;

FIG. 7A is a graph illustrating an MO gas concentration profile in a region 0.1 mm above the wafer stage according to an embodiment of the present invention when the width ratio of the upper surface to the lower surface of the gas inlet baffle is 1.5 or an included angle of the gas inlet baffle is 20°;

FIG. 7B is a graph illustrating an MO gas concentration profile in a region 0.1 mm above the wafer stage according to an embodiment of the present invention when the width ratio of the upper surface to the lower surface of the gas inlet baffle is 3 or an included angle of the gas inlet baffle is 35°;

FIG. 8A is a graph illustrating an MO gas concentration profile in a region 5 mm below the gas inlet baffle according to an embodiment of the present invention when the width ratio of the upper surface to the lower surface of the gas inlet baffle is 1.5 or an included angle of the gas inlet baffle is 12° or 20°; and

FIG. 8B is a graph illustrating an MO gas concentration profile in a region 0.1 mm above the wafer stage according to an embodiment of the present invention when the width ratio of the upper surface to the lower surface of the gas inlet baffle is 1.5 or an included angle of the gas inlet baffle is 12° or 20°.

### DETAILED DESCRIPTION OF THE INVENTION

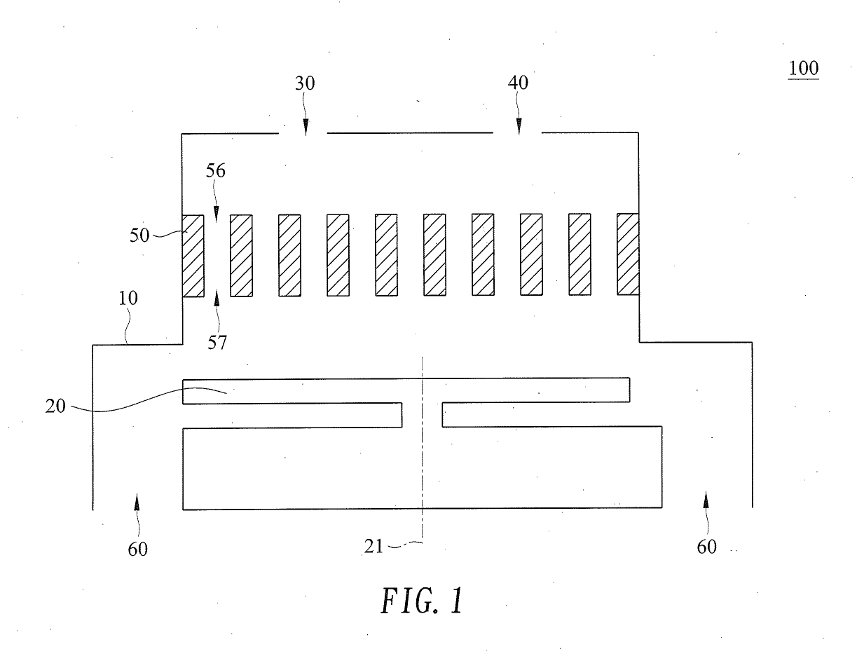

As shown in FIG. 1, an embodiment of the present invention is a metal organic chemical vapor deposition (MOCVD) gas diffusion system 100 with gas inlet baffles 50. The MOCVD gas diffusion system 100 comprises a reaction chamber 10, a wafer stage 20, at least one first gas inlet 30, at least one second inlet 40, a plurality of gas inlet baffles 50 and a gas outlet 60.

As shown in FIG. 1, the reaction chamber 10, which is in the form of a hollow enclosure, is a reaction space in which inlet gases react with each other to deposit a semiconductor crystalline film on an epitaxial wafer surface in the MOCVD gas diffusion system 100.

Also as shown in FIG. 1, the wafer stage 20 is fixedly disposed in the reaction chamber 10 and has a central axis 21. The wafer stage 20 is adapted to support a plurality of wafers and rotate about the central axis 21 so that the semiconductor crystalline film is deposited on the epitaxial wafer surface more uniformly.

As shown in FIG. 1, the first gas inlet 30 is formed at an upper portion 10 of the reaction chamber, and is adapted to input a metal organic (MO) gas. The MO gas may be trimethylgallium (TMGa), trimethylaluminum (TMAl), trimethylindium (TMIn), or bis-cyclopentadienylmagnesium (Cp2Mg).

As shown in FIG. 1, the second gas inlet 40 is also formed at the upper portion of the reaction chamber 10 and separated from the first gas inlet 30. The second gas inlet 40 is adapted to input a hydride gas, which may be arsine (AsH3), phosphine (PH3), NH3, and Si2H6.

As shown in FIG. 1 to FIG. 3, the plurality of gas inlet baffles 50 is obliquely movably disposed under the first gas inlet 30 and the second gas inlet 40. An upper layer opening 56 and a lower layer opening 57 exist between every two adjacent ones of the gas inlet baffles 50 to allow the MO gas or the hydride gas to pass therethrough, and the gas inlet baffles 50 are made of a material that does not react with the MO gas and the hydride gas.

As shown in FIG. 1 to FIG. 3, the gas inlet baffles 50 are detachable and can divide the wafer stage 20 into a plurality of gas inlet regions 23. The MO gas and the hydride gas pass through the upper layer opening 56 and the lower layer opening 57 between the gas inlet baffles 50 to react with each other so that a semiconductor crystalline film is deposited on the epitaxial wafer stage 20 of the gas inlet regions 23.

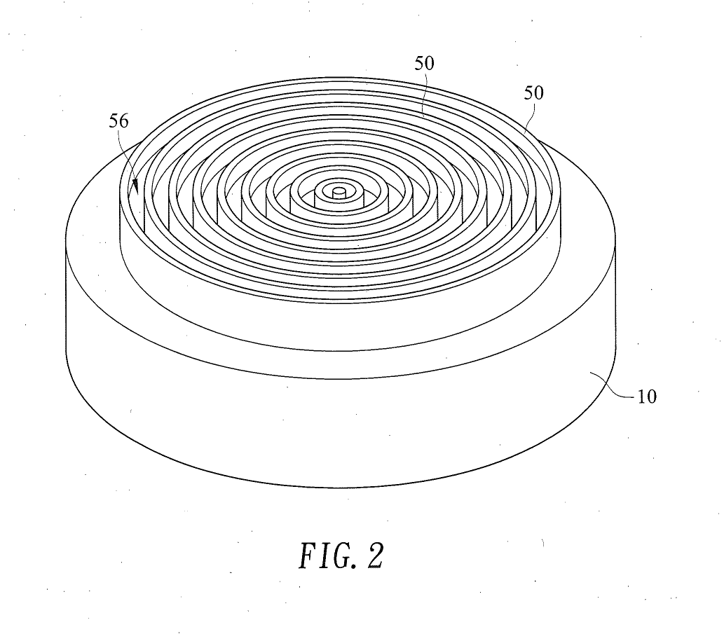

As shown in FIG. 2, each of the gas inlet baffles 50 may be an annular gas inlet baffle 50, and the gas inlet baffles 50 are disposed around a same axis to form a gas inlet baffle 50 in the form of concentric circles.

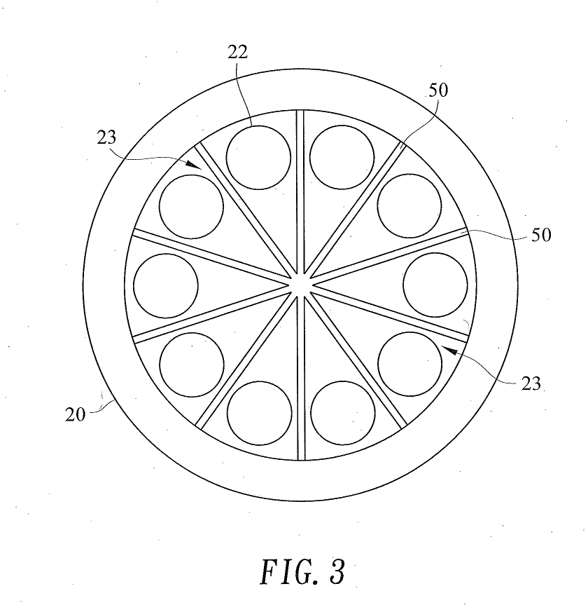

As shown in FIG. 3, the gas inlet baffles 50 may also be sheet-like baffles that are arranged radially from a same axis.

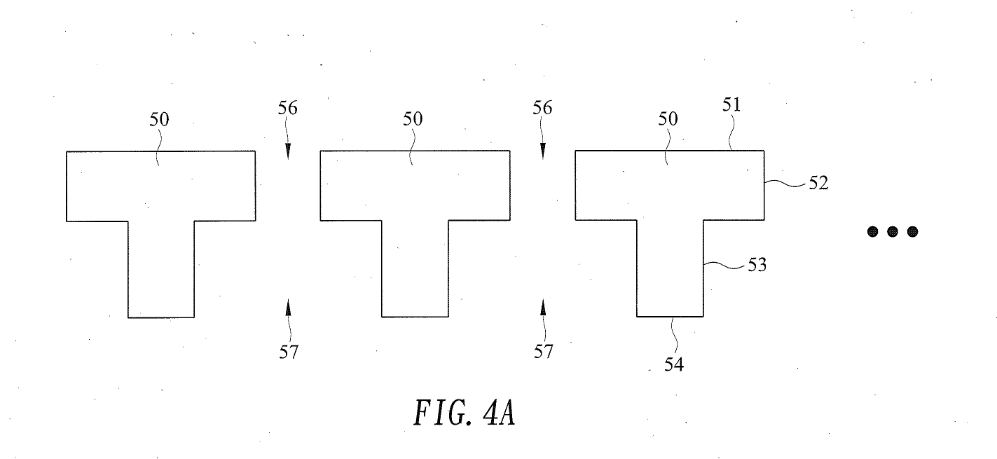

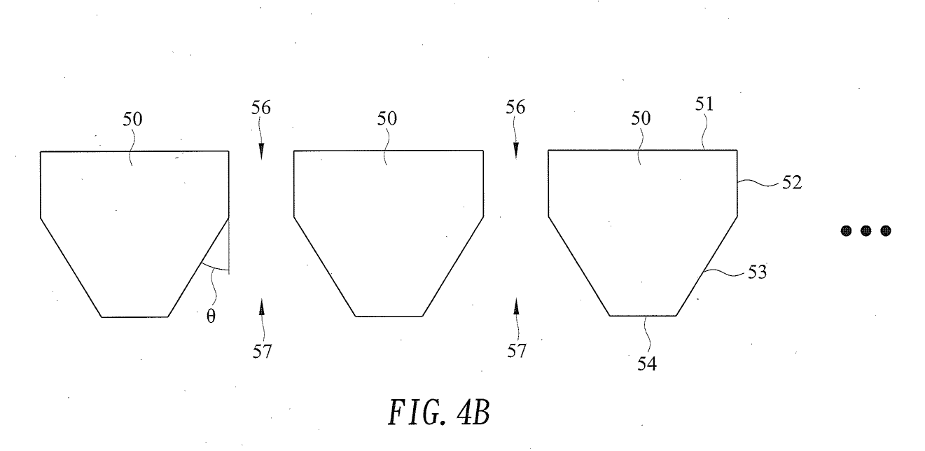

As shown in FIG. 4A and FIG. 4B, each of the gas inlet baffles 50 has an upper surface 51, a first side surface 52 extending from the upper surface 51, a second side surface 53 extending from the first side surface 52 and a lower surface 54 extending from the second side surface 53 and opposite to the upper, surface 51, and the first surface 52 and the second surface 53 include an angle θ therebetween.

As shown in FIG. 4A, the longitudinal cross section of each of the gas inlet baffles 50 may be T-shaped, and different ratios of the width of the upper surface 51 to the width of the lower surface 54 of the gas inlet baffles 50 will lead to different MO gas concentration distributions in the reaction chamber 10.

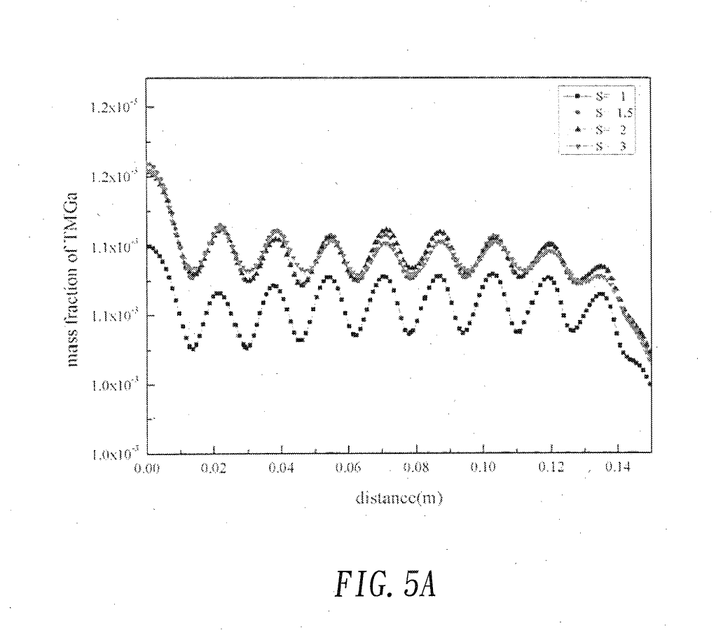

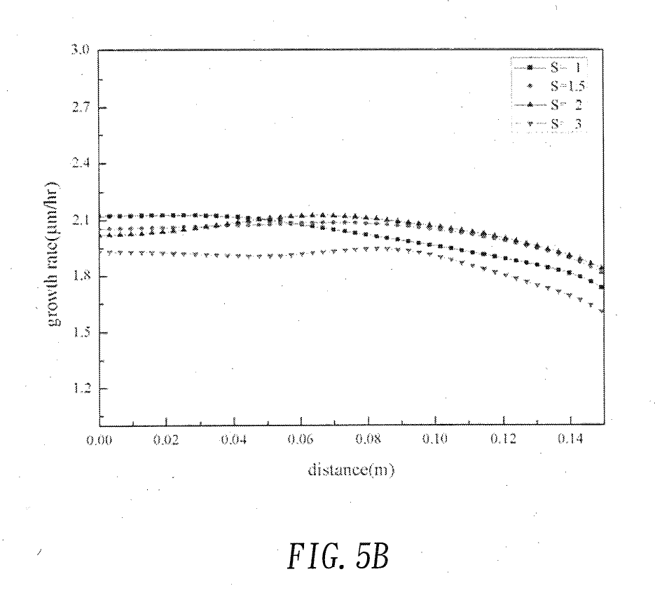

FIG. 5A is a graph illustrating the MO gas concentration versus the distance in a region 5 mm below the gas inlet baffle 50 when different width ratios S of the upper surface 51 to the lower surface 54 of the gas inlet baffle 50 are used according to an embodiment of the present invention. It can be known from the distribution graph shown in FIG. 5A that, as the width ratio of the upper surface 51 to the lower surface 54 of the gas inlet baffle 50 increases, the MO gas concentration in the region 5 mm below the gas inlet baffle 50 also increases. However, if the amount of MO gas inputted from the first gas inlet 30 remains unchanged, then after the width ratio of the upper surface 51 to the lower surface 54 of the gas inlet baffle 50 reaches 1.5:1, the MO gas concentration will not increase significantly any longer.

FIG. 5B is a distribution graph illustrating the growth rate of the semiconductor crystalline film deposited on the epitaxial wafer surface versus the distance when different width ratios S of the upper surface 51 to the lower surface 54 of a gas inlet baffle 50 are used according to an embodiment of the present invention. It can be seen from the distribution graph shown in FIG. 5B that, when the width ratio of the upper surface 51 to the lower surface 54 of the gas inlet baffle is 1.5:1 or 3.0:1, the growth rate of the semiconductor crystalline film deposited on the epitaxial wafer surface is relatively uniform (i.e., the distribution curves are relatively flat). This reveals that, the semiconductor crystalline film deposited on the epitaxial wafer stage 20 is relatively uniform when the width ratio of the upper surface 51 to the lower surface 54 of the gas inlet baffle 50 is 1.5:1 or 3.0:1.

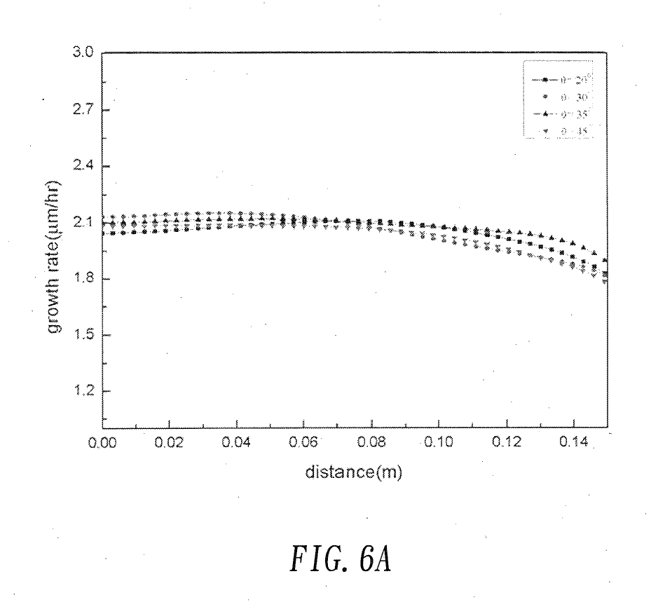

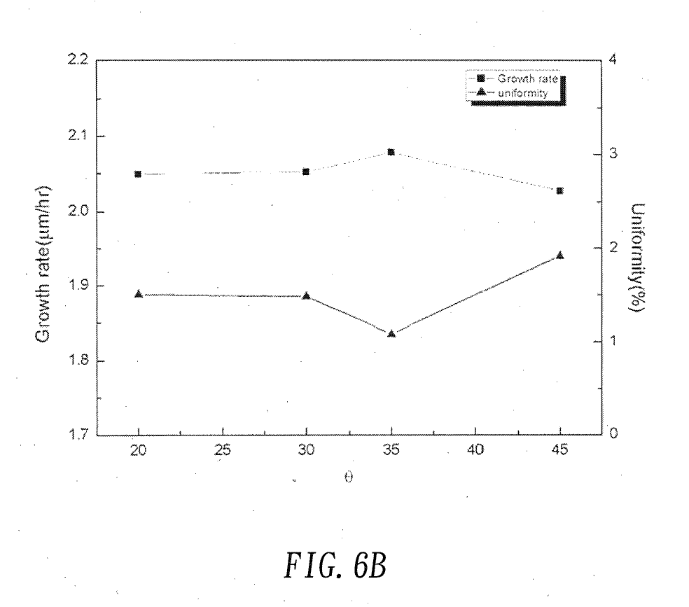

Referring to FIG. 4B and FIG. 6A, FIG. 6A is a distribution graph illustrating the growth rate of the semiconductor crystalline film deposited on the epitaxial wafer surface versus the distance when an angle θ included between the first side surface 52 and the second side surface 53 changes as the gas inlet baffle 50 changes in shape. It can be seen from the distribution graph shown in FIG. 6A that, when the angle 0 is 35°, the growth rate of the semiconductor crystalline film deposited on the epitaxial wafer surface is relatively uniform, i.e., the semiconductor crystalline film deposited on the wafer surface on the wafer stage 20 is relatively uniform.

As shown in FIG. 4B and FIG. 6B, the growth rate of the semiconductor crystalline film deposited on the epitaxial wafer surface differs as the angle θ included between the first side surface 52 and the second side surface 53 of the gas inlet baffle 50 changes. Particularly, the growth rate of the semiconductor crystalline film deposited on the epitaxial wafer surface is optimal when the angle θ is 35°.

As can be known from the above analysis, when an MOCVD gas diffusion system 100 with gas inlet baffles 50 is to be used, the gas inlet baffle 50 according to the embodiment shown in FIG. 4A may be chosen and then an optimal width ratio S of the upper surface 51 to the lower surface 54 is chosen; or alternatively, the gas inlet baffle 50 according to the embodiment shown in FIG. 4B may be chosen and then an optimal angle θ is chosen. A semiconductor crystalline film of the same uniformity and the same thickness can be formed on the epitaxial wafers in either case.

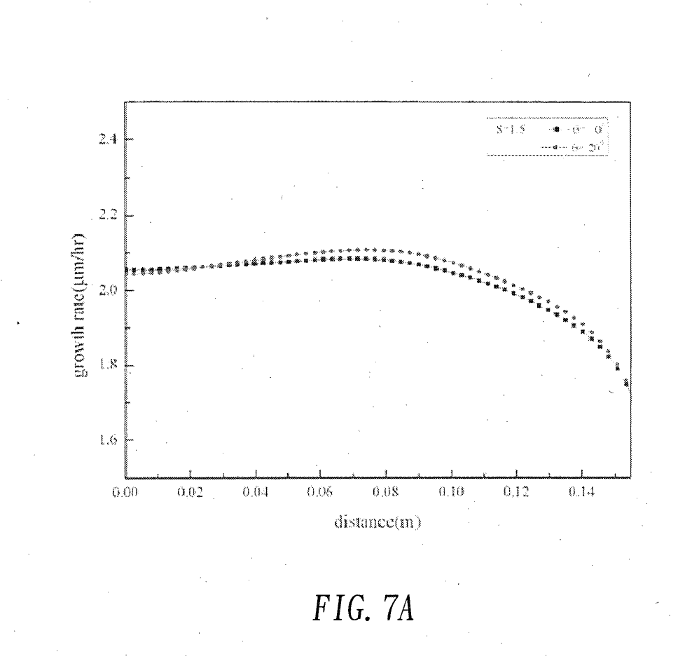

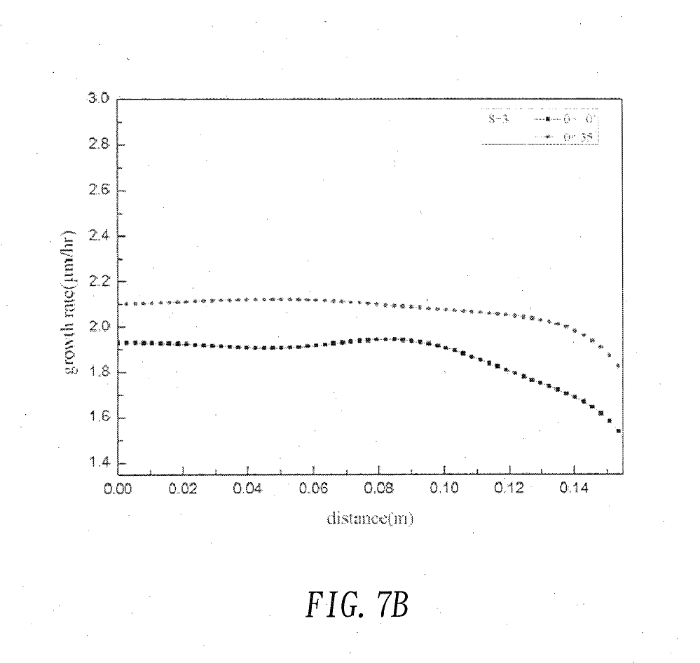

As shown in FIG. 7A, a desirable distribution of the growth rate of the semiconductor crystalline film deposited on the epitaxial wafer surface can be obtained in a region 0.1 mm above the wafer stage 20 when the width ratio S of the upper surface 51 to the lower surface 54 of the gas inlet baffle 50 according to the embodiment shown in FIG. 4A is 1.5 or when the included angle θ of the gas inlet baffle 50 is 20°.

As shown in FIG. 7B, the growth rate of the semiconductor crystalline film deposited on the epitaxial wafer surface has an approximately horizontal distribution in a region above the wafer stage 20 when the width ratio S of the upper surface 51 to the lower surface 54 of the gas inlet baffle 50 according to the embodiment shown in FIG. 4A is 3 or an included angle θ of the gas inlet baffle 50 according to the embodiment shown in FIG. 4B is 35°. This means that the MO gas concentration distribution is relatively uniform. A desirable growth rate of the semiconductor crystalline film deposited on the epitaxial wafer surface can be obtained when the angle θ of the gas inlet baffle 50 is 35° in the embodiment shown in FIG. 4B or when the width ratio S of the upper surface 51 to the lower surface 54 of the gas inlet baffle 50 in the embodiment shown in FIG. 4A is 3.

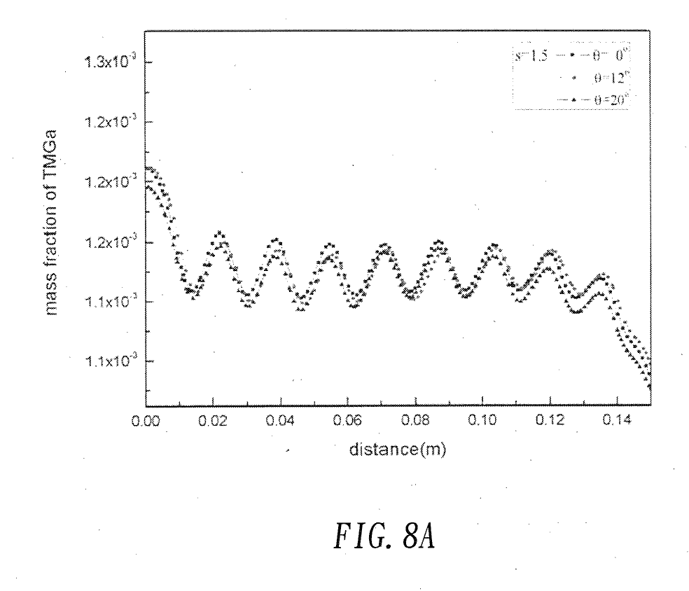

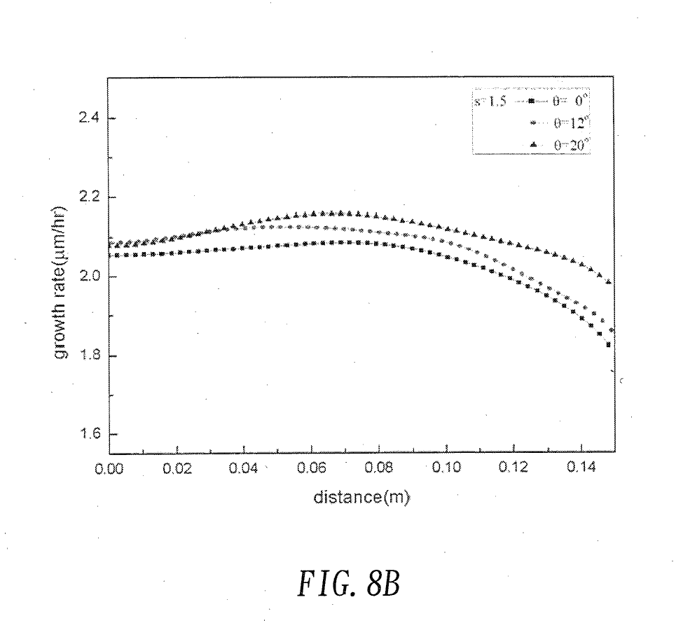

In an embodiment shown in FIG. 5A and FIG. 8A, a high MO gas concentration (i.e., a high utilization factor of MO gas) can be obtained in a region 5 mm below the gas inlet baffle 50 when the width ratio S of the upper surface 51 to the lower surface 54 of the gas inlet baffle 50 according to the embodiment shown in FIG. 4A is 1.5 or the angle θ of the gas inlet baffle 50 is 12° or 20°.

FIG. 8B is a graph illustrating the growth rate of the semiconductor crystalline film deposited on the epitaxial wafer surface versus the distance. An approximately horizontal distribution (i.e., a relatively uniform MO gas concentration distribution) can be obtained when the width ratio S of the upper surface 51 to the lower surface 54 of the gas inlet baffle 50 according to the embodiment shown in FIG. 4A is 1.5 or the angle θ of the gas inlet baffle 50 according to the embodiment shown in FIG. 4B is 12° or 20°.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

1. A metal organic chemical vapor deposition (MOCVD) gas diffusion system with gas inlet baffles, comprising:
a reaction chamber in the form of a hollow enclosure;
a wafer stage, being fixedly disposed in the reaction chamber and having a central axis, the wafer stage being adapted to support a plurality of wafers and rotate about the central axis;
at least one first gas inlet, being formed at an upper portion of the reaction chamber and adapted to input a metal organic (MO) gas;
at least one second gas inlet, being formed at the upper portion of the reaction chamber and separate from the first gas inlet, the second gas inlet being adapted to input a hydride gas;
a plurality of gas inlet baffles, being obliquely movably disposed under the first gas inlet and the second gas inlet, wherein an upper layer opening and a lower layer opening exist between every two adjacent ones of the gas inlet baffles to allow the MO gas or the hydride gas to pass therethrough, and the gas inlet baffles are made of a material that does not react with the MO gas and the hydride gas; and
a gas outlet, being formed at a lower portion of the reaction chamber and adapted to discharge the MO gas or the hydride gas or a mixture of the MO gas and the hydride gas.

2. The MOCVD gas diffusion system of claim 1, wherein each of the gas inlet baffles is an annular gas inlet baffle, and the gas inlet baffles are disposed around a same axis to form a gas inlet baffle in the form of concentric circles.

3. The MOCVD gas diffusion system of claim 1, wherein the gas inlet baffles are sheet-like baffles that are arranged radially from a same axis.

4. The MOCVD gas diffusion system of claim 1, wherein each of the gas inlet baffles has an upper surface, a first side surface extending from the upper surface, a second side surface extending from the first side surface and a lower surface extending from the second side surface and opposite to the upper surface, and the first surface and the second surface include an angle therebetween.

5. The MOCVD gas diffusion system of claim 1, wherein the gas inlet baffles are detachable.

6. The MOCVD gas diffusion system of claim 1, wherein the gas inlet baffles divide the wafer stage into a plurality of gas inlet regions.

7. The MOCVD gas diffusion system of claim 1, wherein the MO gas is one of trimethylgallium (TMGa), trimethylaluminum (TMAl), trimethylindium (TMIn), and bis-cyclopentadienylmagnesium (Cp2Mg).

8. The MOCVD gas diffusion system of claim 1, wherein the hydride is one of arsine (AsH₃), phosphine (PH₃), NH₃, and Si₂H₆.

9. The MOCVD gas diffusion system of claim 2, wherein each of the gas inlet baffles has an upper surface, a first side surface extending from the upper surface, a second side surface extending from the first side surface and a lower surface extending from the second side surface and opposite to the upper surface, and the first surface and the second surface include an angle therebetween.

10. The MOCVD gas diffusion system of claim 3, wherein each of the gas inlet baffles has an upper surface, a first side surface extending from the upper surface, a second side surface extending from the first side surface and a lower surface extending from the second side surface and opposite to the upper surface, and the first surface and the second surface include an angle therebetween.

11. The MOCVD gas diffusion system of claim 2, wherein the gas inlet baffles are detachable.

12. The MOCVD gas diffusion system of claim 3, wherein the gas inlet baffles are detachable.

13. The MOCVD gas diffusion system of claim 2, wherein the gas inlet baffles divide the wafer stage into a plurality of gas inlet regions.

14. The MOCVD gas diffusion system of claim 3, wherein the gas inlet baffles divide the wafer stage into a plurality of gas inlet regions.
